(19) United States
(12) Patent Application Publication
(10) Pub. No.: US 2009/0287493 A1
(43) Pub. Date: Nov. 19, 2009

(54) DIRECT STREAM DIGITAL AUDIO WITH MINIMAL STORAGE REQUIREMENT

(75) Inventors: Erwin Janssen, Eindhoven (NL); Derk Reefman, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/915,478

(22) PCT Filed: May 16, 2006
(86) PCT No.: PCT/IB06/51537

§ 371 Date: Nov. 26, 2007

(30) Foreign Application Priority Data
May 30, 2005 (EP) 05104612.6

(51) Int. Cl. G10L 19/00; H03M 3/00; H03M 1/06

(52) U.S. Cl. 704/500; 341/143; 341/118; 704/E19.001

(57) ABSTRACT

An audio coding scheme allowing PCM signal to lossless DSD signal expansion for next generation optical disc formats. The method of encoding an input DSD signal includes up-sampling a corresponding PCM signal to the DSD sample rate. Then a set of loop filter parameters for a noise-shaping loop of a sigma-delta modulator are generated, either using a random starting condition of the sigma-delta modulator or including synchronization parameters. This will allow a decoder to regenerate an almost perfect signal, but still it needs a correction signal to be able to bit identically regenerate the DSD input signal. Therefore, a correction signal is generated based on a difference between a sigma-delta modulated version of the up-sampled PCM signal and the input DSD signal, wherein the sigma-delta modulated version of the up-sampled PCM signal is obtained using the set of loop filter parameters. The correction signal may be adapted to be applied to the low bit PCM signal, to the up-sampled PCM signal or to the output bit stream. Finally, an expansion bit stream is generated where an encoded version of the set of loop filter parameters and an encoded version of the correction signal are included. The decoder can reproduce the original DSD signal based on the already available PCM signal and the described expansion bit stream. Thus, the coding scheme enables top quality audio with minimal storage overhead since the already available PCM signal is used in combination with an expansion bit stream. Since only an additional data stream is required to be stored on a disc, e.g. as part of an MPEG stream, DSD functionality is added to existing systems without causing compatibility problems.

### FIELD OF THE INVENTION

The invention relates to the field of high quality audio coding. Especially, the invention relates to the field of coding of Direct Stream Digital (DSD) audio data, i.e. bit stream audio data. The invention includes a method of encoding and decoding a DSD signal, an encoder and a decoder for a DSD signal, an encoded DSD signal, and a device including a DSD signal encoder and a device including a DSD decoder.

### BACKGROUND OF THE INVENTION

With the launch of the new optical disc formats HD-DVD and Blu-ray Disc, high resolution video is introduced. With this high-quality video also higher quality PCM audio becomes available. A clear indication of this change is the inclusion of DTS++ lossless audio as mandatory format. Top quality audio as delivered by DSD, the audio format used in the Philips/SONY Super Audio CD, is not yet part of these standards. Although the disc capacity of these new formats is large, the space available for audio data is limited.

EP 0 890 949 A2 describes a digital audio processing system that is capable of receiving an input bit stream signal, or DSD signal, generating a corresponding PCM signal using a decimation filter and a residual data signal based on a difference between the input bit stream and a bit stream generated from a bit stream converted version of the generated PCM signal, this bit stream conversion being carried out by a sigma-delta modulator 33, shown in FIG. 3 of EP 0 890 949 A2. Based on the generated PCM signal and an encoded version of the residual data signal, a bit stream signal, or DSD signal, can be reproduced. Thus, a storage medium between a recording side and reproduction side needs to store only the generated PCM signal and an encoded version of the residual data signal in order to reproduce the input bit stream signal.

However, the system described in EP 0 890 949 A2 has a number of disadvantages. If for example the sigma-delta modulator 33 is different from the original sigma-delta modulator used to generate the input bit stream signal, the generated bit stream may be very different from the input bit stream, and thus the residual data signal will be significant and almost a random signal which is not very compressible. Consequently, the residual data signal will require a large storage capacity.

With the system described in EP 0 890 949 A2, the residual data signal will only require a small amount of storage capacity in case a number of requirements for the sigma-delta modulator 33 relative to the original sigma-delta modulator are fulfilled, namely: that they have identical topologies, have identical order, identical loop filter coefficients, receive identical inputs, and have identical internal states (i.e. start up with the same states and receive the same input from during initialisation). For practical use such requirements will not be fulfilled, since the original sigma-delta modulator can not be assumed to be known, nor are the states transmitted to the receiver, and therefore in practice the system of EP 0 890 949 A2 will produce a residual data signal that requires a large storage capacity.

### SUMMARY OF THE INVENTION

It may be seen as an object of the present invention to provide an encoding method and an encoder capable of losslessly encoding a DSD signal utilising a corresponding PCM signal with a minimum requirement of extra data storage space.

According to a first aspect, the invention provides a method of encoding an input DSD signal based on a corresponding PCM signal, the method comprising the steps of:

1) up-sampling the PCM signal to a sample rate equal to a sample rate of the DSD input signal,
2) generating a set of loop filter parameters for a noise-shaping loop of a sigma-delta modulator,
3) generating a correction signal based on a difference between a sigma-delta modulated version of the up-sampled PCM signal and the input DSD signal, wherein the sigma-delta modulated version of the up-sampled PCM signal is obtained using the set of loop filter parameters, and
4) generating an expansion bit stream comprising an encoded version of the set of loop filter parameters and an encoded version of the correction signal.

With ‘corresponding PCM signal’ is understood a PCM signal, at a low sample rate such as standard CD or DVD format, that has been generated from the input DSD signal, or at least is closely related thereto.

It is to be understood that the ‘set of loop filter parameters’ includes loop filter coefficients and initialization parameters, i.e. starting conditions, that will allow a decoder to set its sigma-delta modulator in accordance therewith and thus be able to regenerate the sigma-delta modulated version of the up-sampled PCM signal. The loop filter parameters can be set to: 1) random but known values for loop filter coefficients and initial states or conditions of the loop filter (i.e. a not synchronized case), or 2) special determined values for the loop filter coefficients and initial states or conditions of the loop filter (a synchronized case).

In the not synchronized case, the loop filter coefficients cannot be truly random, but a person skilled in the art is able to derive an almost infinite number of valid sets. For the initial conditions of the loop filter the number of possibilities is even larger, but again the skilled person will know how to choose initial states that will provide a working system.

The encoding method is advantageous in that it provides the possibility of providing an encoded lossless DSD audio signal by utilizing an already existing corresponding low bit rate PCM signal and an expansion bit stream which only requires a minimum of extra storage space. Thus, the method is advantageous for use in connection with storing of multi-format audio data on an optical storage media with limited storing space available.

According to step 2) of the method, sigma-delta modulator loop filter parameters, e.g. loop filter coefficients and initial states, are included in the expansion bit stream and thus made available at the decoder side. It is therefore possible to select or optimize these loop filter parameters such that the sigma-delta modulator will output, based on the input DSD signal and the up-sampled PCM signal, an almost correct bit stream, i.e. a bit stream which is almost identical to the input DSD signal.

A correction signal, or error signal, is finally extracted based on a difference between the almost correct bit stream and the input DSD signal. Since it is possible to select or optimize the loop filter parameters at the encoding side so as to ensure that the difference between the output of the sigma-delta modulator, i.e. the almost correct bit stream, and the input DSD signal is minimal, only a small amount of correction is needed for recreation of the bit identical input DSD signal from the almost correct bit stream. Thus, the correction signal or correction bit stream will also be minimal, such as ‘0’ most of the time, and therefore the correction signal can be highly compressed in step 4).

Another way to select the loop filter parameters, such as initialization parameters and loop filter coefficients, is to randomly choose the initialization parameters. Still it is possible to force an output DSD signal at the decoder side to be bit identical to the input DSD signal as long as the filter coefficients and initialization parameters are included in the expansion bit stream and thus made available to the decoder.

The loop filter parameters that are included into the expansion bit stream can also be represented with a very small amount of data, and since these parameters only need to be updated at a low frequency, the expansion bit stream can altogether be represented using a small bit rate compared to the that of the PCM signal representation.

Altogether the method according to the first aspect provides lossless DSD audio quality with the addition of an expansion bit stream that only requires a minimum of extra data storage capacity compared to the storage capacity of the PCM signal itself.

In addition, since the method is based on providing DSD audio quality using a PCM signal, DSD audio quality can be combined with backward compatibility. E.g. the encoding method is well suited to be used to store a DSD audio signal on a storage medium, e.g. on a DVD disc. Such DVD disc can still be played by a conventional DVD player without DSD capability, since such player will only use the PCM signal, while DSD equipment, e.g. Super Audio CD capable players, can profit from the additional low bit rate DSD expansion bit stream to regenerate the original DSD quality based on the PCM signal. E.g. the expansion bit stream can be part of an MPEG stream.

In preferred embodiments the method comprises optimizing the loop filter parameters based on minimizing a difference between a sigma-delta modulated version of the up-sampled PCM signal and the input DSD signal. The purpose of this optimization is to ensure that the output bit stream of the sigma-delta modulator is as close as possible to the input DSD signal. Thereby, the correction signal only needs to correct small errors and thus, the correction signal will have a nature that causes it to be highly compressible and thus the correction signal only requires a small extra data rate.

Preferably, step 3) comprises generating the correction signal so that it provides, together with the sigma-delta modulated version of the up-sampled PCM signal, a bit stream being identical to the DSD input signal. Hereby, the DSD input signal can be bit identically recreated at the decoder side using the PCM signal and the expansion bit stream.

The correction signal generated in step 3) may be adapted to be applied at different positions in a signal path from PCM signal input to output bit stream from the sigma-delta modulator. Naturally, in order to be able to recreate the input DSD signal at the decoder side, the correction signal should be applied in the same position in the signal path as it was intended during encoding. The correction signal may be adapted to be applied to the PCM signal, i.e. to the PCM signal before it is up-sampled. The correction may alternatively be adapted to be applied to the up-sampled version of the PCM signal. In yet other alternatives, the correction signal may be adapted to be applied in connection to the sigma-delta modulator. The correction signal may be adapted to be applied either inside or outside the noise-shaping loop of the sigma-delta modulator. The correction signal may, in still another alternative, be adapted to be applied to an internal state of the sigma delta modulator.

For embodiments where the set of loop filter parameters is initialized with not specifically derived values, i.e. not the synchronized case), it is preferred to generate a correction signal to be applied to the up-sampled PCM signal.

More than one correction signal may be generated and included into the expansion bit stream, e.g. correction signals adapted to be applied to different positions in the signal paths, such as a combination of two or more of the aforementioned possibilities. Step 3) may comprise an optimization procedure with the purpose of deriving a combination of two or more of the aforementioned possible correction signals that altogether requires a minimum of storage for its representation. The reason for such optional optimization is that, for certain input DSD signals, it may be so that a combination of two or more correction signals adapted to be applied at different positions in the signal path may require a bit rate lower than what can be obtained in case only one correction signal is used.

The correction signal may be based on a difference between the sigma-delta modulated version of the up-sampled PCM signal and the input DSD signal. Most preferably, the correction signal is derived so as to ensure that the difference between the sigma-delta modulated version of the up-sampled PCM signal and the input DSD signal becomes zero.

Preferably, the input DSD signal is split into frames (e.g. 1/75 second, 37632 DSD samples) before being applied to the encoding method.

Since step 4) comprises including the loop filter parameters in the expansion bit stream, the selected loop filter parameters are known at the decoder side—whether optimized or (more or less) randomly chosen. Also, the PCM signal will be available since it will be stored e.g. on a DVD disc such as required by existing DVD standards. Thus, with the loop filter parameters and the correction signal available at the decoder side, it is possible to bit identically recreate the input DSD signal.

The encoding method may further comprise the step of storing the PCM signal and the expansion bit stream on a storage medium.

In a second aspect, the invention provides a method of generating an output DSD signal based on a PCM signal and an expansion bit stream, the method comprising the steps of

1) generating a set of loop filter parameters and a correction signal by decoding the expansion bit stream,
2) up-sampling the PCM signal to a sample rate equal to a sample rate of the DSD output signal,
3) generating the output DSD signal based on a bit stream obtained by sigma-delta modulating the up-sampled PCM signal using the set of loop filter parameters,

the method further comprises applying the correction signal in connection with at least one of steps 2) and 3).

The advantages, function and embodiments mentioned in relation to the first aspects apply to the decoding method according to the second aspect since the second aspect defines a method of generating a DSD signal based on a PCM signal and an expansion bit stream such as generated according to the method of the first aspect. The correction signal should of course be applied in accordance with that intended by the encoding method, thus the same possibilities exist for the correction signal as set forth in connection to the first aspect: to the (low rate) PCM signal, to the up-sampled signal, inside the noise-shaping loop of the sigma-delta modulator, outside the noise-shaping loop of the sigma-delta modulator, to an internal state of the sigma-delta modulator, or to an output bit stream from the sigma-delta modulator. In addition, up-sampling of the PCM signal should be performed using e.g. the same filter as was used in the encoding process.

In a third aspect, the invention provides an audio encoder adapted to encode an input DSD signal based on a corresponding PCM signal, the audio encoder comprising:
an up-sampling unit adapted to generate an up-sampled version of the PCM signal with a sample rate equal to the DSD input signal,
a sigma-delta modulator with a set of loop filter parameters adapted to generate a bit stream signal based on the up-sampled PCM signal,
a correction signal generator adapted to generate a correction signal based on a difference between the bit stream signal and the input DSD signal, and
encoding means adapted to encode the set of loop filter parameters and encode the correction signal and include these encoded signals in an expansion bit stream.

The same advantages, function and embodiments as set forth in relation to the first aspect apply to the third aspect which essentially defines an audio encoder adapted to perform the method defined in the first aspect. Thus, the encoder may comprise optimizing means adapted to optimize the set of loop filter parameters, and the correction signal generator may be adapted to generate the correction signal so that is adapted to be applied: to the (low rate) PCM signal, to the up-sampled signal, inside the noise-shaping loop of the sigma-delta modulator, outside the noise-shaping loop of the sigma-delta modulator, to an internal state of the sigma-delta modulator, or to an output bit stream from the sigma-delta modulator. A combination of two or more of these correction signal options may be used.

The encoder may be implemented using software or hardware or a combination thereof. Preferably, the encoder comprises computing means, e.g. a signal processor.

In a fourth aspect, the invention provides an audio decoder adapted to generate an output DSD signal based on a PCM signal and an expansion bit stream signal, the audio decoder comprising
a decoder adapted to decode the expansion bit stream signal and generate a set of loop filter parameters and a correction signal in response thereto,
an up-sampling unit adapted to generate an up-sampled version of the PCM signal with a sample rate equal to the DSD output signal,
a sigma-delta modulator adapted to generate a bit stream signal in response to the up-sampled version of the PCM signal by using the set of loop filter parameters,
an output generator adapted to apply the correction signal and generate the output DSD signal based on the generated bit stream, and
a signal corrector adapted to apply the correction signal in at least one of: the up-sampling unit, the sigma-delta modulator and the output generator.

The same advantages, function and embodiments as set forth in relation to the second aspect apply to the fourth aspect which essentially defines an audio decoder adapted to perform the method defined in the second aspect. The decoder may be implemented using software or hardware or a combination thereof. Preferably, the decoder comprises computing means, e.g. a signal processor.

In a fifth aspect, the invention provides a device comprising an encoder according to the third aspect. The device may be audio/video devices, e.g. DVD recorders, DVD hard disk recorders, surround sound equipment, HD-DVD recorders, Blue-ray Disc recorders, etc.

In a sixth aspect, the invention provides a device comprising a decoder according to fourth aspect. The device may be audio devices, e.g. Super Audio CD players, DVD players and recorders, DVD hard disk recorders, HD-DVD players and recorder, Blue-ray Disc players and recorders, surround sound equipment etc.

In a seventh aspect, the invention provides an encoded audio signal comprising
a PCM signal, and
an expansion bit stream comprising an encoded version of a set of loop filter parameters for a sigma-delta modulator and an encoded version of a correction signal.

The advantages of such encoded audio signal is apparent from the above explanation in relation to the first aspect. The encoded audio signal according to the seventh aspect is well suited for storage on a storage medium since it allows DSD sound quality to be stored with a relatively limited storage capacity. For the same reason, the encoded audio signal is well suited for transmission, e.g. on the Internet, since it allows DSD sound quality to be transmitted at a relatively low data rate. The expansion bit stream may be part of an MPEG layer.

In an eighth aspect, the invention provides a storage medium having stored thereon an encoded audio signal according to the seventh aspect. The storage medium may be a hard disk, a floppy disk, a CD, a DVD, an SD card, a memory stick, a memory chip etc.

In further aspects, the invention provides a computer executable program code adapted to perform the method according to the first aspect. Further, the invention provides a computer executable program code adapted to perform the method according to the second aspect.

### BRIEF DESCRIPTION OF THE DRAWINGS

In the following the invention is described in more details with reference to the accompanying figures, of which

FIG. 1 shows a system of a preferred encoder and a preferred decoder with intermediate signal storage on a storage medium,

FIG. 2 shows an encoder embodiment,

FIG. 3 shows a another encoder embodiment,

FIG. 4 shows a decoder embodiment,

FIG. 5 shows a decoder embodiment with indication of different correction signal options.

While the invention is susceptible to various modifications and alternative forms, specific embodiments have been shown by way of example in the drawings and will be described in detail herein. It should be understood, however, that the invention is not intended to be limited to the particular forms disclosed. Rather, the invention is to cover all modifications, equivalents, and alternatives falling within the spirit and scope of the invention as defined by the appended claims.

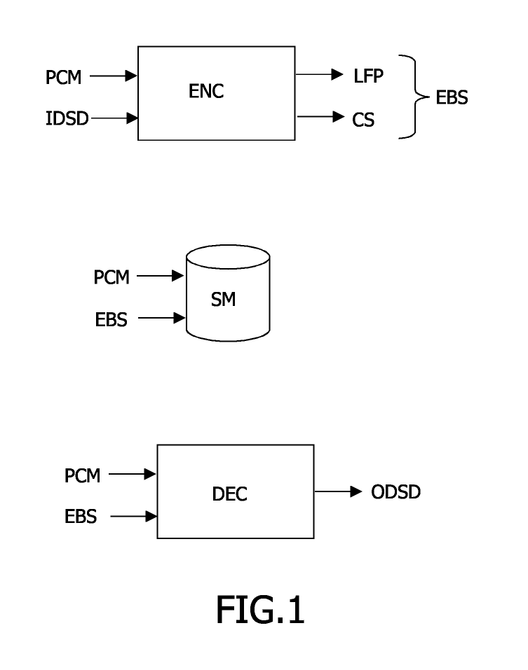

FIG. 1 shows a block diagram of an encoder ENC and a decoder DEC according to the invention and a storage medium SM, such as an optical disk, to intermediately store the encoded signal from the encoder ENC. The encoder ENC is adapted to receive an input DSD signal IDSD and a corresponding PCM signal PCM, e.g. a DTS signal, and generate an expansion bit stream EBS in response thereto, the expansion bit stream EBS enabling the decoder DEC to recreate the input DSD signal from the PCM signal PCM. The expansion bit stream EBS comprises a set of sigma-delta modulator noise-shaping loop filter parameters LFP and a correction signal CS, both the loop filter parameters LFP and the correction signal CS are preferably included in the expansion bit stream EBS in encoded form. The correction signal CS can be encoded using, for example, Run Length Encoding, LZW or arithmetic coding.

Thus, the expansion bit stream EBS can be stored on a storage medium SM together with the PCM signal PCM requiring only a small amount of extra storage capacity compared to the PCM signal PCM alone. The decoder DEC creates an output DSD signal ODSD which is bit identical with the input DSD signal IDSD based on the PCM signal PCM and the expansion bit stream EBS.

In the encoder, the following steps are performed: 1) derive loop filter parameters LFP, 2) determine a correction signal CS, and finally pack and compress the loop filter parameters LFP and the correction signal(s) CS. Different options exist for the correction signal. It can be determined by the encoder ENC to be applied in the decoder DEC to the PCM signal PCM, to an up-sampled version of the PCM signal or as a bit correction signal, i.e. a signal to be added to subtracted from an intermediate bit stream—either inside or outside a sigma-delta modulator noise-shaping loop. The correction signal CS can, if preferred, comprise a plurality of separate correction signals, such as any combination of the mentioned ones, since this can prove to provide, with a given input DSD signal IDSD, the most storage efficient way to store the required correction. Thus, the encoding method may include the step of optimising a correction signal CS by comparing different options of a single correction signal of the mentioned types or a combination of several of the mentioned types.

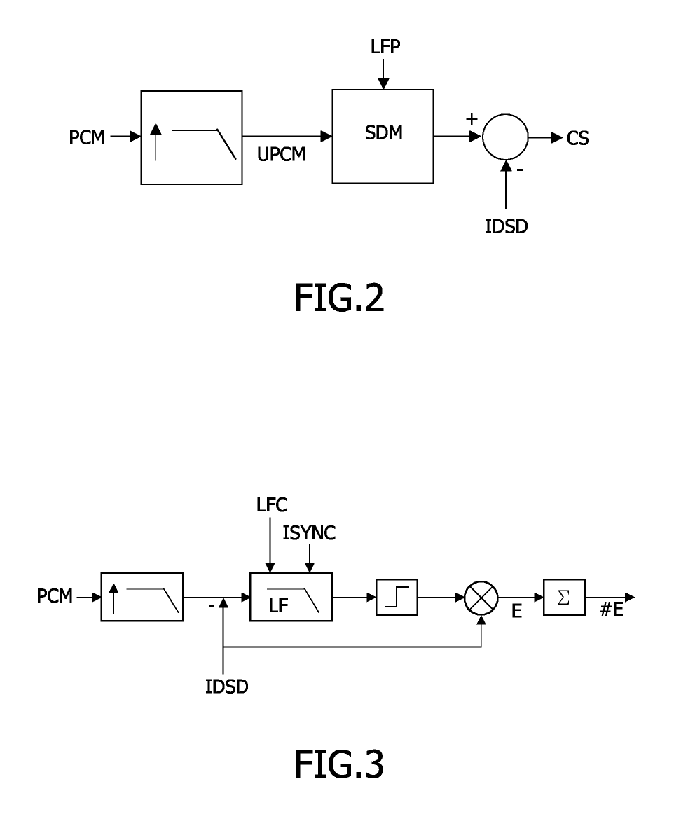

FIG. 2 shows a preferred encoder embodiment adapted to encode an input DSD signal IDSD based on a corresponding but low sample rate PCM signal PCM. An up-sampled version UPCM of the PCM signal PCM is first generated using an up-sampling filter. The up-sampled PCM signal UPCM is up-sampled to the sample rate of the input DSD signal IDSD. Next, the up-sampled PCM signal UPCM is sigma-delta modulated in a sigma-delta modulator SDM that has a noise-shaping loop with a set of loop filter parameters LFP. Different strategies for selecting the loop filter parameters LFP may be chosen. The sigma-delta modulated version of the up-sampled PCM signal UPCM is then subtracted by the input DSD signal IDSD in order to generate a bit stream representing an error signal or correction signal CS.

With knowledge of corresponding correction signal CS and loop filter parameters LFP used by the sigma-delta modulator SDM, it is possible for a decoder to recreate the input DSD signal IDSD by sigma-delta modulating an up-sampled version of the PCM signal UPCM using the loop filter parameters LFP by adding the correction signal to the output of the sigma-delta modulator. The decoder should use the same up-sampling filter to generate the UPCM signal that was used by the encoder.

FIG. 3 shows an embodiment where loop filter coefficients LFC and integrator synchronization parameters ISYNC for the loop filter LF of the sigma-delta modulator are extracted. Inputs to the process comprise an input DSD signal IDSD, and a corresponding PCM signal PCM. The PCM signal PCM can be generated by performing decompression of DTS and DTS++ data to obtain the original lossless PCM signal. Note that the waveform of lossy compressed PCM signal (e.g. AC3) does in general not resemble the waveform of the original PCM signal, and is therefore less suited to this scheme.

The low rate PCM signal PCM is next up-sampled to the DSD sample rate in an up-sampling filter. By use of the input DSD signal IDSD, an error signal E is generated, and a number of errors #E can be counted. With the given input data, the settings, i.e. LFC and ISYNC, that result in the minimal number of errors #E are then calculated. Optimization of the optional PCM correction signal(s) can be embedded in this step. Once the optimal settings have been derived, the bit correction signal (for correction inside noise-shaping loop) is equal to the error signal indicated in the FIG. 3. Note that this signal can be zero with correctly chosen PCM correction signal(s), correctly chosen LFC and synchronization parameters ISYNC.

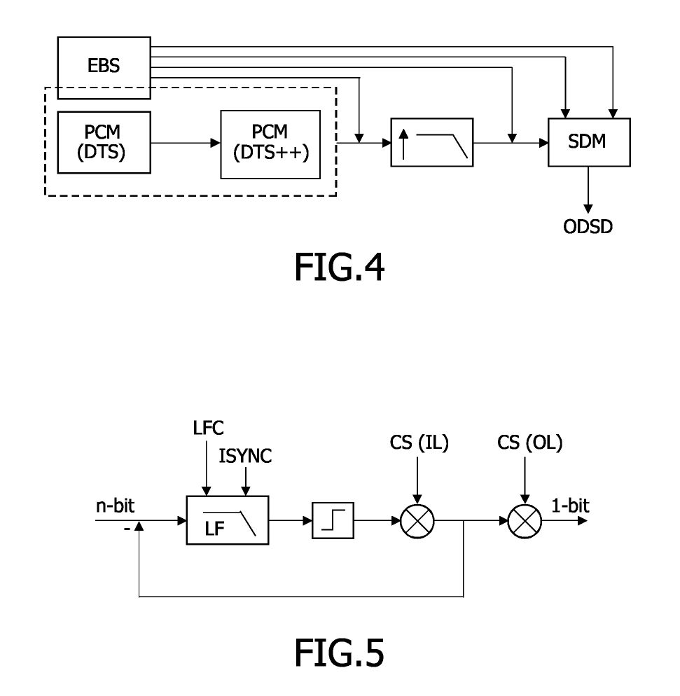

FIG. 4 shows a decoder embodiment that is able to regenerate a bit-identical DSD signal from the available PCM stream PCM (DTS) and an expansion bit stream EBS. The DTS++ decoded stream low rate PCM signal PCM (DTS++) is input and up-sampled to the DSD rate. A correction signal may be applied to the low rate PCM signal PCM (DTS++) or to the up-sampled PCM signal or to both. The up-sampled PCM signal is input to a sigma-delta modulator SDM with synchronization. The sigma-delta modulator SDM may be adapted to apply a bit correction—either inside or outside its noise-shaping loop. Thus, altogether four possible correction signals can be retrieved from the expansion bit stream EBS, indicated by the four arrows starting from the expansion bit stream EBS. Any combination of these options for correction signals can be used to guarantee a bit-identical reconstruction so as to ensure that the output DSD signal ODSD of the sigma-delta modulator SDM is bit identical to the original source DSD signal that has been encoded. Decompression of the expansion bit stream EBS is not shown.

FIG. 5 shows a decoder embodiment with a sigma-delta modulator with synchronization and bit correction possibility such as was also shown in the encoder embodiment of FIG. 3. The sigma-delta modulator receives a multi bit input signal n-bit and outputs a bit stream indicated by 1-bit. The sigma-delta modulator has an input ISYNC for synchronizing the loop-filter integrators and an input LFC for setting loop filter coefficients. These two inputs ISYNC, LFC will need to be updated at a low rate. In addition, the sigma-delta modulator receives a bit correction signal CS. This bit correction signal CS can be applied at two different locations as indicated, namely inside the noise-shaping loop CS (IL) or outside the noise-shaping loop CS (OL). The signal runs at the DSD sample rate.

Crucial in this scheme is the derivation of the loop filter synchronization parameters ISYNC. Since the source DSD signal as well as the source PCM signal is available at the encoder side, the synchronization parameters ISYNC can be calculated to a very high degree of precision. Philips patent U.S. Pat. No. 6,606,043 B2 describes how to synchronize the integrator states of an arbitrary sigma-delta modulator to a bit-stream. This idea can be extended to also retrieve loop-filter coefficients for better synchronization. The low rate PCM and up-sampled PCM correction signal can as well be derived using a similar scheme.

If the sigma-delta modulator is synchronized correctly, its output caused by the PCM input will be almost identical to the source DSD. Since not all bits will be correct, either the PCM input signal, or the bit-stream output signal will need to be corrected sometimes. If only correction is applied to the low rate PCM signal, the output will never be 100% correct. If correction is applied to the up-sampled PCM signal, with correct synchronization, the output can be 100% correct. By applying correction to both low rate and up-sampled PCM signals, possibly the required storage is smaller than when only applying to the up-sampled PCM signal.

By applying a correction to the up-sampled PCM signal, the output bits can be made correct. The required changes to the up-sampled signal will be small, thus this correction signal can be compressed. By also applying a correction to the low-rate PCM signal, the required corrections at the up-sampled PCM signal can be made smaller, thereby potentially reducing overall required storage. By correcting the quantized bits, the correction can be applied in the noise-shaping loop or outside the loop. Since the quantized signal is 1-bit, the bit correction signal is also a 1-bit signal. Typically, the bit correction signal consists of zeros (‘0’). Only when the quantized output is incorrect, the bit correction signal will contain a one (‘1’). Because of the nature of this signal it can be efficiently stored in compressed form. Any combination of the mentioned options can be used to find the minimum size correction signals.

A system comprising an encoder and a decoder according to the invention may be seen as a PCM signal to DSD expansion system since it will allow lossless DSD functionality on existing storage media since it is possible to provide DSD sound quality based on an already existing PCM signal and a small amount of extra data, i.e. the expansion bit stream.

Reference signs in the claims merely serve to increase readability. These reference signs should not in any way be construed as limiting the scope of the claims, but are included only with the purpose of illustrating examples.

1. A method of encoding an input DSD signal (IDSD) based on a corresponding PCM signal (PCM), the method comprising the steps of:
1) up-sampling the PCM signal (PCM) to a sample rate equal to a sample rate of the DSD input signal (IDSD),
2) generating a set of loop filter parameters (LFP) for a noise-shaping loop of a sigma-delta modulator,
3) generating a correction signal (CS) based on a difference between a sigma-delta modulated version of the up-sampled PCM signal and the input DSD signal (IDSD), wherein the sigma-delta modulated version of the up-sampled PCM signal is obtained using the set of loop filter parameters (LFP), and
4) generating an expansion bit stream (EBS) comprising an encoded version of the set of loop filter parameters (LFP) and an encoded version of the correction signal (CS).

2. Method according to claim 1, wherein step 2) comprises optimizing the set of loop filter parameters (LFP) based on minimizing a difference between a sigma-delta modulated version of the up-sampled PCM signal and the input DSD signal (IDSD).

3. Method according to claim 1, wherein step 3) comprises generating the correction signal (CS) so that it provides, together with the sigma-delta modulated version of the up-sampled PCM signal, a bit stream being identical to the DSD input signal (IDSD).

4. Method according to claim 1, wherein step 3) comprises generating a correction signal (CS) adapted to be applied to the PCM signal (PCM).

5. Method according to claim 1, wherein step 3) comprises generating a correction signal (CS) adapted to be applied to the up-sampled version of the PCM signal.

6. Method according to claim 1, wherein step 3) comprises generating a correction signal (CS) adapted to be applied to an internal state of the sigma-delta modulator.

7. Method according to claim 1, wherein step 3) comprises generating a correction signal (CS) adapted to be applied in connection with the noise-shaping loop of the sigma-delta modulator.

8. Method of generating an output DSD (ODSD) signal based on a PCM signal (PCM) and an expansion bit stream (EBS), the method comprising the steps of
1) generating a set of loop filter parameters (LFP) and a correction signal (CS) by decoding the expansion bit stream (EBS),
2) up-sampling the PCM signal (PCM) to a sample rate equal to a sample rate of the DSD output signal (ODSD),
3) generating the output DSD signal (ODSD) based on a bit stream obtained by sigma-delta modulating the up-sampled PCM signal using the set of loop filter parameters (LFP),
the method further comprises applying the correction signal (CS) in connection with at least one of steps 2) and 3).

9. An audio encoder (ENC) adapted to encode an input DSD signal (IDSD) based on a corresponding PCM signal (PCM), the audio encoder (ENC) comprising:
an up-sampling unit adapted to generate an up-sampled version of the PCM signal with a sample rate equal to the DSD input signal (IDSD),
a sigma-delta modulator with a set of loop filter parameters (LFP) adapted to generate a bit stream signal based on the up-sampled PCM signal,
a correction signal generator adapted to generate a correction signal (CS) based on a difference between the bit stream signal and the input DSD signal (IDSD), and
encoding means adapted to encode the set of loop filter parameters (LFP) and encode the correction signal (CS) and include these encoded signals in an expansion bit stream (EBS).

10. An audio decoder (DEC) adapted to generate an output DSD signal (ODSD) based on a PCM signal (PCM) and an expansion bit stream signal (EBS), the audio decoder (DEC) comprising
a decoder adapted to decode the expansion bit stream signal (EBS) and generate a set of loop filter parameters (LFP) and a correction signal (CS) in response thereto,
an up-sampling unit adapted to generate an up-sampled version of the PCM signal with a sample rate equal to the DSD output signal (ODSD),
a sigma-delta modulator adapted to generate a bit stream signal in response to the up-sampled version of the PCM signal by using the set of loop filter parameters (LFP),
an output generator adapted to apply the correction signal (CS) and generate the output DSD signal (ODSD) based on the generated bit stream, and
a signal corrector adapted to apply the correction signal (CS) in at least one of: the up-sampling unit, the sigma-delta modulator and the output generator.

11. Device comprising an encoder (ENC) according to claim 9.

12. Device comprising a decoder (DEC) according to claim 10.

13. An encoded audio signal comprising
a PCM signal (PCM), and
an expansion bit stream (EBS) comprising an encoded version of a set of loop filter parameters (LFP) for a sigma-delta modulator and an encoded version of a correction signal (CS).

14. A storage medium (SM) having stored thereon an encoded audio signal according to claim 13.
